(19) United States
(12) Patent Application Publication
(10) Pub. No.: US 2026/0334254 A1
(43) Pub. Date: Oct. 22, 2026

(54) ELECTRONIC PACKAGE AND SUBSTRATE THEREOF

(71) Applicant: SILICONWARE PRECISION INDUSTRIES CO., LTD., Taichung City (TW)

(72) Inventors: Yu-Chen CHEN, Taichung City (TW); Szu-Hsien CHEN, Taichung City (TW)

(73) Assignee: SILICONWARE PRECISION INDUSTRIES CO., LTD., Taichung City (TW)

(21) Appl. No.: 19/635,615

(22) Filed: Mar. 31, 2026

(30) Foreign Application Priority Data
Apr. 17, 2025 (TW) 114114592

(51) Int. Cl. H10W 70/63; H10W 72/30

(52) U.S. Cl. CPC H10W 70/63; H10W 72/332

(57) ABSTRACT

Provided are an electronic package and a substrate structure thereof. The substrate structure includes a substrate body, contact pads, and parallel conductive modules. The contact pads are disposed on a surface of the substrate body, and the parallel conductive modules are disposed within the substrate body with one end of connected to the contact pad. The contact pads are configured for power supply, and the parallel conductive modules increase current path branching to reduce resistance.

### BACKGROUND

### 1. Technical Field

The present disclosure relates to a semiconductor structure, and more particularly, to an electronic package and a substrate structure thereof.

### 2. Description of Related Art

With the rapid development of the electronics industry, electronic products have trended towards thinner, smaller, lighter, and multifunctional designs, and semiconductor packaging technology have been developed accordingly in various forms. To satisfy requirements for high integration and miniaturization of semiconductor devices, flip-chip packaging structures have been widely adopted in the industry. In addition, whether electronic products can achieve desired characteristics of reduced size, weight, and power consumption, as well as increased operating speed, largely depends on advancements in chip memory capacity, bandwidth, and reduced operating voltage. However, the continued improvement of memory capacity, operating frequency, and voltage reduction is closely related to the degree of chip integration on the chip and the density of input/output (I/O) connectors used for signal and power transmission.

Taking a ball grid array (BGA) semiconductor device as an example, as chip designs continue to increase in I/O counts, signal routing is required to fan out from a high-density solder ball region. Therefore, signal solder balls are typically arranged in outer rows of the chip, while power solder balls are forced to be arranged closer to an inner region of the chip. However, when power supply pads or solder balls are distributed at locations far apart, current paths become excessively long, which increases resistance and causes excessive voltage drop, thereby potentially resulting in circuit damage.

Therefore, how to overcome the above-mentioned problems of the prior art has become an urgent issue to be resolved.

### SUMMARY

In view of the aforementioned shortcomings of the prior art, the present disclosure provides a substrate structure which comprises: a substrate body having a die attach area defined on a surface thereof; a plurality of contact pads disposed within the die attach area; and at least one parallel conductive module disposed within the substrate body and connected to at least one of the contact pads.

The present disclosure further provides an electronic package which comprises: a substrate structure including a substrate body having a die attach area defined on a surface thereof, a plurality of contact pads disposed within the die attach area, and at least one parallel conductive module disposed within the substrate body and connected to at least one of the contact pads; and an electronic component disposed on the die attach area of the substrate structure and electrically connected to the plurality of contact pads.

In the aforementioned electronic package and the substrate structure thereof, the substrate body is a core substrate or a coreless substrate.

In the aforementioned electronic package and the substrate structure thereof, a portion of the contact pads are configured for signal transmission, and another portion of the contact pads are configured for power supply; and the parallel conductive module is configured to provide power and is electrically connected to the contact pad configured for power supply.

In the aforementioned electronic package and the substrate structure thereof, the parallel conductive module includes a first parallel conductive path, a second parallel conductive path, a conductive via, and at least one shunt via.

In the aforementioned electronic package and the substrate structure thereof, the conductive via includes opposite ends, the shunt via is disposed adjacent to and in parallel with the conductive via and includes opposite ends; and the conductive via and the shunt via are connected to the first parallel conductive path at ends on the same side thereof, and are connected to the second parallel conductive path at ends on the other side thereof.

In the aforementioned electronic package and the substrate structure thereof, the first parallel conductive path is connected to the contact pad, and the second parallel conductive path is connected to an interconnect layer in the substrate body.

In the aforementioned electronic package and the substrate structure thereof, a plurality of parallel conductive modules are formed within the substrate body.

In the aforementioned electronic package and the substrate structure thereof, a distance between a contact pad connected to one of the parallel conductive modules and an edge of the die attach area is different from a distance between another contact pad connected to another one of the parallel conductive modules and the edge of the die attach area.

In the aforementioned electronic package and the substrate structure thereof, the plurality of the parallel conductive modules respectively include different numbers of shunt vias.

In the aforementioned electronic package and the substrate structure thereof, the parallel conductive module connected to a contact pad located farther from an edge of the die attach area includes a higher number of shunt vias than the parallel conductive module connected to a contact pad located closer to the edge of the die attach area.

Accordingly, the electronic package and the substrate structure of the present disclosure mainly form parallel conductive modules within the substrate body, such that current paths are increased to provide branching along an entire power loop, thereby reducing resistance.

### BRIEF DESCRIPTION OF THE DRAWINGS

FIG. 1 is a schematic cross-sectional view of a first embodiment of a substrate structure according to the present disclosure.

FIG. 2 is a schematic top view of the first embodiment of a substrate structure according to the present disclosure.

FIG. 3 is a schematic cross-sectional view of a second embodiment of a substrate structure according to the present disclosure.

FIG. 4 is a schematic cross-sectional view of an electronic package according to the present disclosure.

### DETAILED DESCRIPTION

The following describes the embodiments of the present disclosure with examples. A person ordinarily skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by a person ordinarily skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “beneath,” “first,” “second,” “a,” “one,” and the like are merely used for clear explanation rather than limiting the practicable scope of the present disclosure, and thus, alterations or adjustments of the relative relationships thereof without essentially altering the technical contents should still be considered in the practicable scope of the present disclosure.

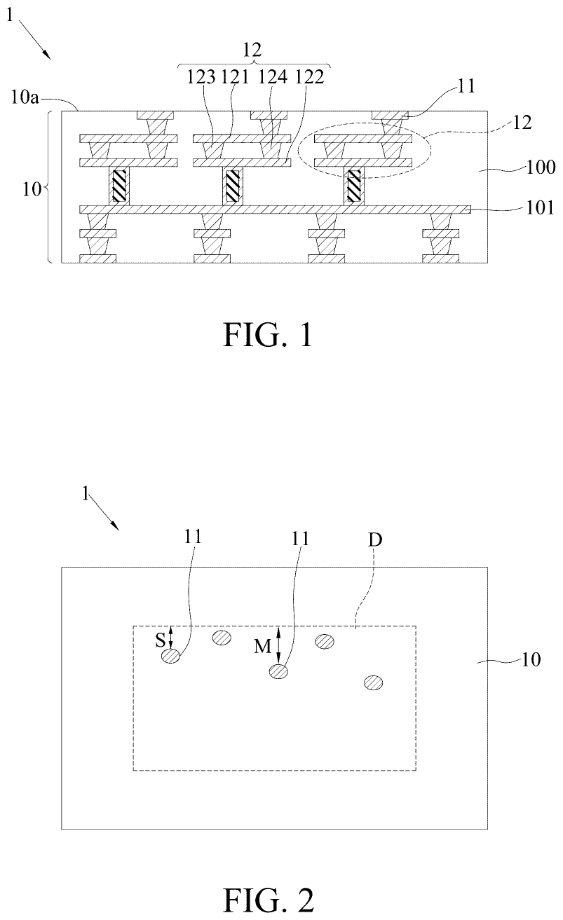

Please refer to FIG. 1 and FIG. 2, which are schematic cross-sectional and top views of a first embodiment of a substrate structure according to the present disclosure.

A substrate structure 1 is, for example, a packaging substrate used for carrying semiconductor chips, which includes a substrate body 10, a plurality of contact pads 11, and at least one parallel conductive module 12.

A substrate body 10 is, for example, a substrate with a core or a coreless substrate. The plurality of contact pads 11 are formed on the surface 10a of the substrate body 10, the surface 10a defines with a die attach area D, and the plurality of contact pads 11 are formed within the die attach area D.

In an embodiment, the substrate body 10 includes an insulating layer 100 and an interconnect layer 101 bonded to the insulating layer 100. The interconnect layer 101 is, for example, a fan-out redistribution layer (RDL), and the plurality of contact pads 11 are formed on an outmost layer of the interconnect layer 101. The die attach area D allows electronic components such as semiconductor chips or passive elements to be disposed thereon.

Furthermore, the interconnect layer may be made of copper, and the insulating layer 100 may be made of dielectric materials, such as polybenzoxazole (PBO), polyimide (PI), prepreg (PP), and the like.

The parallel conductive module 12 is formed in the substrate body 10. One end of the parallel conductive module 12 is connected to at least one of the contact pads 11, and the other end thereof is connected to the interconnect layer 101. A portion of the contact pads 11 are used for signal transmission, and another portion of the contact pads 11 are used for power supply. The parallel conductive module is designed for power supply and is electrically connected to the contact pad 11 used for power supply.

The parallel conductive module 12 includes a first parallel conductive path 121, a second parallel conductive path 122, a conductive via 123, and at least a shunt via 124.

In an embodiment, the conductive via 123 and the shunt via 124 may be formed in a type of a conductive blind via. The conductive via 123 includes two opposite ends, and the shunt via 124 is arranged adjacent to and in parallel with the conductive via 123 and includes two opposite ends. The conductive via 123 and the shunt via 124 are connected to the first parallel conductive path 121 at ends on the same side thereof, and are connected to the second parallel conductive path 122 at ends on the other side thereof. Further, the first parallel conductive path 121 is connected to the contact pad 11 (for example, through a conductive blind via), and the second parallel conductive path 122 is connected to the interconnect layer 101 within the substrate body 10. Accordingly, increasing the number of current paths through shunt vias 124 in addition to an originally single power routing, branching is provided along an entire power loop, thereby reducing resistance. Consequently, the contact pad 11 used for power supply is connected to the parallel conductive module 12, the resistance is reduced through the shunt vias 124 of the parallel conductive module 12, thereby preventing power supply issues.

In addition, a plurality of parallel conductive modules 12 may be formed within the substrate body 10. A contact pad 11 connected to one parallel conductive module 12 is located at a distance S from an edge of the die attach area D, which is different from a distance M between an edge of the die attach area D and another contact pad 11 connected to another parallel conductive module 12 (as shown in FIG. 2). For example, the distance S is shorter than the distance M, and the positions of the contact pads 11 may be arranged according to a actual requirements.

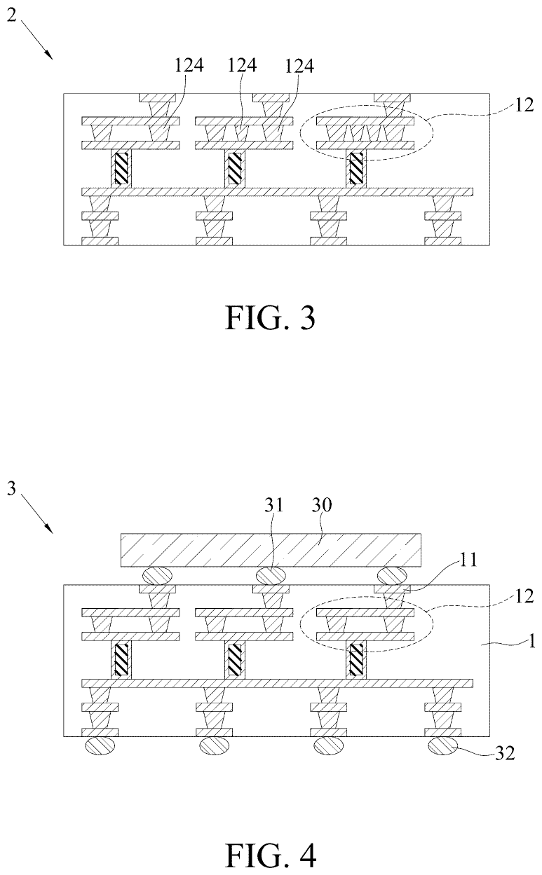

Please simultaneously refer to FIG. 3, which is a schematic cross-sectional view of a second embodiment of a substrate structure 2 according to the present disclosure. The second embodiment is substantially identical to the first embodiment. The major difference is that the plurality of parallel conductive modules 12 are formed within the substrate body 10, and the plurality of parallel conductive modules 12 respectively include different numbers of shunt vias 124. For example, the plurality of parallel conductive modules 12 may respectively include one, two, three, or multiple shunt via(s) 124, and the number of the shunt via(s) 124 may be modified according to actual power requirements. Corresponding to FIG. 2, a number of the shunt vias 124 of the parallel conductive modules 12 connected to the contact pad 11 located at a farther distance M from an edge of the die attach area D is greater than a number of the shunt via(s) 124 of the parallel conductive modules 12 connected to the contact pad 11 located at a shorter distance S from the edge of the die attach area D. Accordingly, even when the power contact pads are distributed farther away such that the current path becomes longer, the overall power loop may still be provided with additional branches by increasing the number of shunt vias (124), thereby reducing resistance.

Please refer to FIG. 4, which is a schematic cross-sectional view of an electronic package 3 according to the present disclosure. An electronic component 30 is disposed on the aforementioned substrate structure 1, and the electronic component 30 is electrically connected to the substrate structure 1.

The aforementioned electronic component 30 is an active element, a passive element, or a combination thereof and is disposed on a die attach area of the substrate structure 1. The active element is, for example, a semiconductor chip, and the passive element is, for example, a resistor, a capacitor, or an inductor.

In an embodiment, the electronic component 30 is a semiconductor chip, which is disposed on the plurality of contact pads 11 in a flip-chip manner via a plurality of conductive bumps 31, such as soldering materials, and is electrically connected to the parallel conductive modules 12.

Additionally, a plurality of conductive elements 32 may be disposed on another surface of the substrate structure 1, such that the electronic component 3 may be electrically connected to an external device through the plurality of conductive elements 32.

To sum up, the electronic package and the substrate structure of the present disclosure mainly form parallel conductive modules within the substrate body, such that current paths are increased to provide branching along an entire power loop, thereby reducing resistance.

What is claimed is:

1. A substrate structure, comprising:
a substrate body having a die attach area defined on a surface thereof;
a plurality of contact pads disposed within the die attach area; and
at least one parallel conductive module disposed within the substrate body and connected to at least one of the contact pads.

2. The substrate structure of claim 1, wherein the substrate body is a core substrate or a coreless substrate.

3. The substrate structure of claim 1, wherein a portion of the contact pads are configured for signal transmission, and another portion of the contact pads are configured for power supply, and wherein the parallel conductive module is configured to provide power and is electrically connected to the contact pad configured for power supply.

4. The substrate structure of claim 1, wherein the parallel conductive module includes a first parallel conductive path, a second parallel conductive path, a conductive via, and at least one shunt via.

5. The substrate structure of claim 4, wherein the conductive via includes opposite ends, the shunt via is disposed adjacent to and in parallel with the conductive via and includes opposite ends, and wherein the conductive via and the shunt via are connected to the first parallel conductive path at ends on the same side thereof, and are connected to the second parallel conductive path at ends on the other side thereof.

6. The substrate structure of claim 4, wherein the first parallel conductive path is connected to the contact pad, and the second parallel conductive path is connected to an interconnect layer in the substrate body.

7. The substrate structure of claim 4, wherein a plurality of parallel conductive modules are formed within the substrate body.

8. The substrate structure of claim 7, wherein a distance between a contact pad connected to one of the parallel conductive modules and an edge of the die attach area is different from a distance between another contact pad connected to another one of the parallel conductive modules and the edge of the die attach area.

9. The substrate structure of claim 7, wherein the plurality of the parallel conductive modules respectively include different numbers of shunt vias.

10. The substrate structure of claim 7, wherein the parallel conductive module connected to a contact pad located farther from an edge of the die attach area includes a higher number of shunt vias than the parallel conductive module connected to a contact pad located closer to the edge of the die attach area.

11. An electronic package, comprising:
a substrate structure including a substrate body having a die attach area defined on a surface thereof, a plurality of contact pads disposed within the die attach area, and at least one parallel conductive module disposed within the substrate body and connected to at least one of the contact pads; and
an electronic component disposed on the die attach area of the substrate structure and electrically connected to the plurality of contact pads.

12. The electronic package of claim 11, wherein the substrate body is a core substrate or a coreless substrate.

13. The electronic package of claim 11, wherein a portion of the contact pads are configured for signal transmission, and another portion of the contact pads are configured for power supply, and wherein the parallel conductive module is configured to provide power and is electrically connected to the contact pad configured for power supply.

14. The electronic package of claim 11, wherein the parallel conductive module includes a first parallel conductive path, a second parallel conductive path, a conductive via, and a shunt via.

15. The electronic package of claim 14, wherein the conductive via includes opposite ends, and the shunt via is disposed adjacent to and in parallel with the conductive via and includes opposite ends, and wherein the conductive via and the shunt via are connected to the first parallel conductive path at ends on the same side thereof, and the conductive via and the shunt via are connected to the second parallel conductive path at ends on the other side thereof.

16. The electronic package of claim 14, wherein the first parallel conductive path is connected to the contact pad, and the second parallel conductive path is connected to an interconnect layer formed in the substrate body.

17. The electronic package of claim 14, wherein a plurality of parallel conductive modules are formed within the substrate body.

18. The electronic package of claim 17, wherein a distance between a contact pad connected to one of the parallel conductive module and an edge of the die attach area is different from a distance between another contact pad connected to another one of the parallel conductive modules and the edge of the die attach area.

19. The electronic package of claim 17, wherein the plurality of the parallel conductive modules respectively include different numbers of the shunt vias.

20. The electronic package of claim 17, wherein the parallel conductive module connected to a contact pad located farther from an edge of the die attach area includes a higher number of the shunt vias than the parallel conductive module connected to a contact pad located closer to the edge of the die attach area.
